(19) United States
(12) Patent Application Publication
(10) Pub. No.: US 2010/0319768 A1
(43) Pub. Date: Dec. 23, 2010

(54) THIN-FILM SOLAR CELL AND PROCESS FOR ITS MANUFACTURE

(75) Inventors: Emily Mitchell, New South Wales (AU); Stefan Reber, Gundelfingen (DE); Evelyn Schmich, Frankfurt (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: FRAUNHOFER-GESELLSCHAFT ZUR FORDERUNG DER ANGEWANDTEN FORSCHUNG e.V, Munchen (DE)

(21) Appl. No.: 12/808,040

(22) PCT Filed: Dec. 8, 2008
(86) PCT No.: PCT/EP08/10401

§ 371 Date: Aug. 12, 2010

(30) Foreign Application Priority Data
Dec. 14, 2007 (EP) 07024276.3

(51) Int. Cl. H01L 31/04; H01L 31/18

(52) U.S. Cl. 136/256; 438/98; 257/E31.124; 257/E31.11

(57) ABSTRACT

The present invention refers to a thin-film solar cell which is contacted from the rear-side. The invention is based on a combination of thin-film solar cells, e.g. wafer equivalents, with the emitter wrap-through (EWT) technology. The present invention also provides a process for manufacturing these solar cells.

The present invention refers to a thin-film solar cell which is contacted from the rear-side. The invention is based on a combination of thin-film solar cells, e.g. wafer equivalents, with the emitter wrap-through (EWT) technology. The present invention also provides a process for manufacturing these solar cells.

The development of thin-film solar cells is known from the prior art for years. The idea is to use a low-cost substrate to save material costs. The solar cell is deposited onto a substrate, e.g. epitaxially with silicon, and the resultant structure can be similar to a standard wafer solar cell.

In the prior art, three types of thin-film solar cells exist in dependence of the type of substrate used.

The first type of substrate is glass, which is popular since it can serve the double purpose of cell encapsulation. However, glass softens at temperatures between 600 and 700° C. making glass only usable for low-temperature cell processing. In general, these cells use transparent conducting oxides (TCOs) as front-side contact.

A second type of substrates used for thin-film solar cells are high-temperature substrates, such as ceramics or low-grade silicon making these substrates processable in high-temperature processing. Thus, much higher cell efficiencies can be reached. As the substrate is not transparent, the front of the cell, i.e. where the light enters, must be the thin-film side of the substrate. In this configuration, the cell resembles a wafer solar cell, hence the name “wafer equivalent”.

For a third type of thin-film solar cell, the thin-film is grown on a high-temperature substrate and subsequently transferred to a low-temperature substrate, e.g. glass.

The background of another aspect of the present invention refers to the emitter wrap-through (EWT) technology which was published for the first time in Gee, J. M., W. K. Schubert, et al. (1993), Emitter-wrap-through solar cell. Proceedings of the 23^{rd} IEEE Photovoltaics Specialists Conference, Louisville, Ky., USA, IEEE; New York, N.Y., USA. The EWT cell concept involves making via holes through the substrate and extending the emitter layer through these holes so that it can be contacted from the rear-side. The base contact must also still be contacted from the rear-side so an interdigitated contact pattern is formed. Various process techniques have been applied to create the rear contact pattern including diffusion barriers and screen printing, laser defined and plated contacts and phosphorous aluminium co-diffusion.

Presently, many research groups are developing techniques for the fabrication of EWT solar cells. Some topics of focus in the published work are the various metallisation techniques, e.g. photolithography, electroless plating or screen-printing, the various rear-side structuring techniques, e.g. laser definition or Al—P codiffusion, rear-side passivation, increasing the rear-side emitter coverage and cell modelling. The vast majority of the EWT technology relates to standard silicon wafer solar cells. One concept of EWT cells is described in Thorp, D. (1998), A Low-temperature Deposited-silicon Selective-emitter-wrap-through Si Solar Cell, Proceedings of the 2^{nd} World Conference on Photovoltaic Energy Conversion, Vienna, Austria, European Commission, Ispra, Italy, 1998, based on a standard silicon wafer EWT cell. Silicon layers were deposited at low temperature therein-through via holes from the rear-side as contact layers. A single metal layer was applied and then scribed with a laser to form the interdigitated pattern. An additional dielectric layer was used to protect the substrate since the substrate was not damageable.

It is an advantage that some thin-film solar cells can be metallized with the standard wafer solar cell metallization techniques. However, there is an industrial trend towards rear-side contacting because it has several benefits: There is no shading from the metal contact grid; the emitter can be optimized for the blue response; the contacts can be optimized for low series resistance; module fabrication is simpler and cells can more densely be packed in a module.

Therefore, the technical problem of the present invention was to provide solar cells eliminating the drawbacks of the mentioned solar cells having a high efficiency and to provide a process for their manufacture which is easy to handle and is based on existing process technologies.

This technical problem is solved by the solar cell with the features of claim 1 and the process having the features of claim 13. The further dependent claims refer to further embodiments.

According to the present invention, a thin-film solar cell with a front-side, i.e. where the light enters, and a rear-side is provided having the following components:
a non-solar-grade substrate having at least one via hole connecting the front-side with the rear-side;
at least one photovoltaically active base layer deposited on the substrate and at least one emitter layer formed at least in regions of the front-side and wrapped through said via hole from the front-side to the rear-side providing an emitter wrap-through (EWT) contact; and
at least one emitter contact region and at least one base contact region on the rear-side insulated from each other.

Preferably, the fraction of the rear-side which is covered by the emitter layer is minimised or eliminated.

Thus, a solar cell has been provided for the first time based on a low-cost substantially photovoltaically inactive substrate on which at least one photovoltaically active base is deposited and emitter layers are formed which are wrapped through via holes contacting the solar cell from the rear-side.

Preferably, at least one isolation layer is deposited between the contact region and the base layer and/or the substrate.

It is preferred that the solar cell on its front-side further comprises a passivating layer which preferably is deposited on the emitter layer. This layer further preferably has anti-reflective properties and preferably consists of a dielectric material, e.g. silicon dioxide, silicon carbide, silicon nitride or mixtures thereof.

A first inventive solar cell concept is based on an electrically conductive material, which preferably is doped silicon, e.g. non-solar grade silicon with a low minority-carrier lifetime. In that case, the substrate acts as a conduction path to the base region, i.e. the base layer. It is necessary that the conductive substrate has to be masked from the emitter contact region which is located on the rear-side of the solar cell. Therefore, preferably an insulating layer is used for the separation of conductive substrate and emitter contact region. Such an insulating layer can be deposited before the formation of the via holes as well as after the deposition of the base and emitter layers on the substrate.

A second inventive concept is based on an electrically non-conductive, i.e. insulating substrate. Also comprised by this concept is a solar cell embodiment having an insulating intermediate layer between substrate and base and emitter layers. Although the substrate cannot be used to conduct the base current, it is possible to wrap the base layers entirely around the substrate while the emitter layer is not wrapped around entirely or has at least one region, preferably on the rear-side, which is free of an emitter layer.

The photovoltaically active material is preferably a semiconductor, in particular a group IV semiconductor, a group III/V semiconductor or a group II/VI semiconductor, e.g. silicon, GaAs and CdTe are preferred.

According to the present invention, also a process for the manufacture of a thin-film solar cell is provided. This process comprises the following steps:
a) Depositing at least one photovoltaically active base layer and forming at least one emitter layer on a non-solar grade substrate having via holes, wherein the layers are applied on the front-side surface, in the via holes and partially on the rear-side of the substrate;
b) Depositing at least one isolation layer on the rear-side of the substrate, covering the entire rear-surface but not covering the entire inner surface of the holes; and
c) Forming at least one emitter contact region and at least one base contact region on the rear-side insulated from each other.

It is further preferred that the at least one emitter contact region and the at least one base contact region at the rear-side of the solar cell are formed from one continuous, electrically conductive layer which is entirely deposited on the rear-side. This layer is subsequently structured, e.g. by a laser, in said emitter and base contact regions.

It is a further option that the deposition of the photovoltaically active base layer and the emitter layer is performed from the gas phase, e.g. by chemical vapour deposition, possibly epitaxially.

Preferably, a passivation layer is deposited on the front-side subsequent to step a). This passivation layer preferably consists of a dielectric material and is anti-reflective. However, the passivation layer can also be deposited on the front-side of the solar cell subsequent to step c).

A preferred embodiment refers to the deposition of the base and emitter layers in-situ as complete pn-structure. However, it is also possible to deposit the base layer in step a) and forming the emitter layer subsequently by diffusion.

The present invention is further explained by the following figures which show special embodiments which shall not limit the present invention to these embodiments.

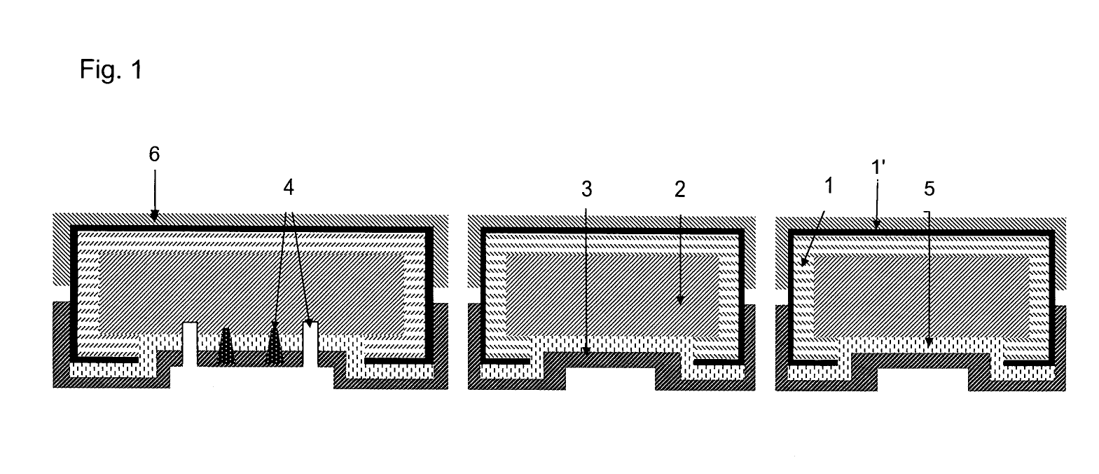

FIGS. 1 to 9 show cross-sectional views of different inventive embodiments of the present invention.

FIG. 1 shows a first embodiment of the inventive solar cell in a cross-sectional view.

Both the base layer 1 and the emitter layer 1′ of the solar cell are wrapped through the via holes in the low-cost substrate 2. This is achieved by depositing the layers of the solar cell simultaneously over the front surface of the substrate and directly into the holes. The substrate may be highly doped and highly conductive. Therefore, it can be used to conduct current laterally to the base contacts, allowing more flexibility with the design of the interdigitated contact. It is also possible to use an insulating substrate in which case the deposited base must be used for conduction. The rear surface of the substrate can be damaged without lowering the efficiency of the solar cell which greatly simplifies the definition of the interdigitated contact pattern. Metal 3 can be deposited over the entire rear surface and then the base and emitter contact regions can be isolated with a laser 4. This is essentially a self-aligning process because the regions must only be aligned to the pre-drilled holes and a large tolerance is allowed. Further layers shown in FIG. 1 are the isolating dielectric layer 5 and the passivating anti-reflection coating 6.

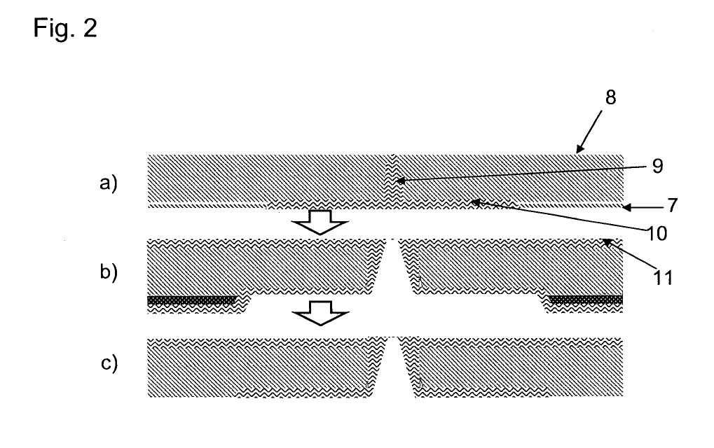

FIG. 2 shows schematically the steps for producing the inventive solar cells. In a first step (FIG. 2a), a dielectric layer 7 is applied to the rear surface of the substrate 8. A narrow via hole 9 having a diameter between 50 and 100 μm is drilled by laser in the substrate 8. Furthermore, circles 10 with a diameter of about 300 μm are ablated with a laser. The dielectric layer 7, e.g. a layer of PECVD-SiO₂, can act as an etch mask during the via laser-damage etch. The second step (FIG. 2b) refers to an epitaxial deposition of the photovoltaically active layer 11 on the front-side and the rear-side as well as the via hole surfaces of the substrate. FIG. 2c) shows a lift-off process by under-etching the dielectric layer 7.

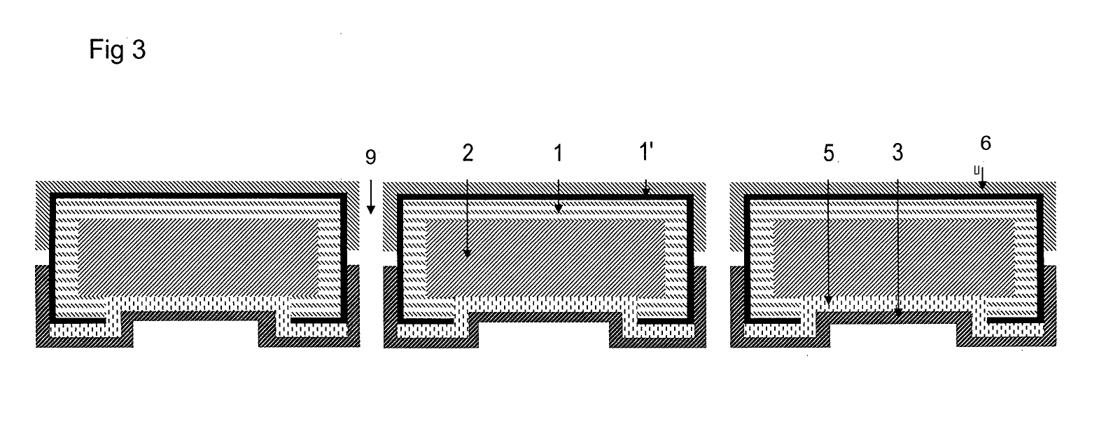

FIG. 3 depicts a further embodiment of the inventive solar cell having a conductive substrate in cross-section. If the substrate is conductive, e.g. heavily p-type doped low-grade silicon, then it acts as a conduction path to the base region. Therefore, the substrate must be masked from the emitter metal contact which is deposited over the entire rear surface. For that purpose, an insulating layer, e.g. possible silicon carbide is used, which is either deposited before the via holes are formed or after the solar cell deposition. The holes 10 are formed in the conductive low-cost substrate 2. The solar cell base layer 1 and emitter layer 1′ are deposited consecutively in a single deposition process, e.g. epitaxy. An insulating film 5, e.g. silicon carbide, is deposited before the metal emitter contact layer 3, e.g. evaporated or screen-printed aluminium, is formed over the entire rear surface and partially through the holes. If the insulating film is deposited before the hole formation then an extra rear-side emitter diffusion step, e.g. phosphorous, may be required after the solar cell deposition to prevent shunting.

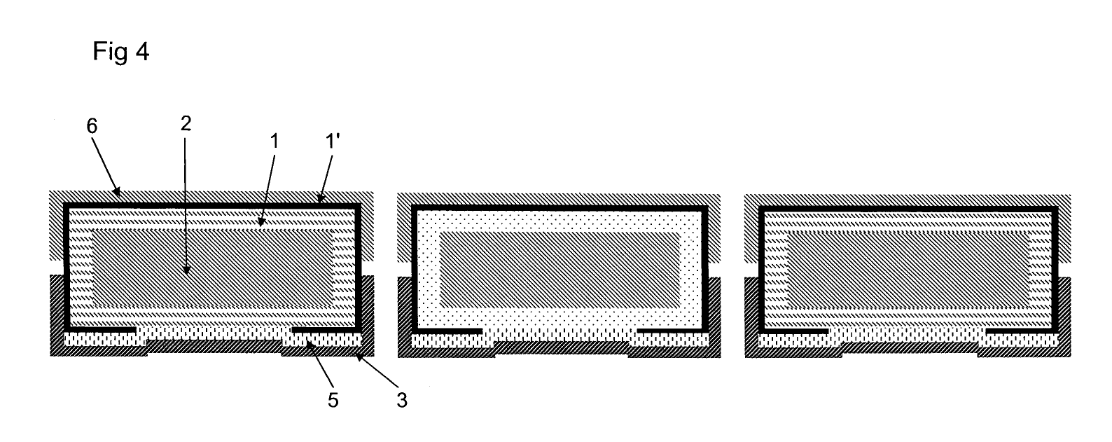

FIG. 4 is an illustration of a further embodiment having an insulating substrate. If the substrate is non-conductive or if an isolating intermediate layer between substrate and solar cell layers is present, then it cannot be used to conduct the base current. It is still possible to realize the cell concept if the deposited solar cell base wraps entirely around the substrate but the deposited emitter does not, or is partially removed after deposition. The only difference is that both the emitter and base currents are conducted laterally through the layers and down through the via holes. A low resistance conduction path can be created in the base layer with a back-surface field (BSF).

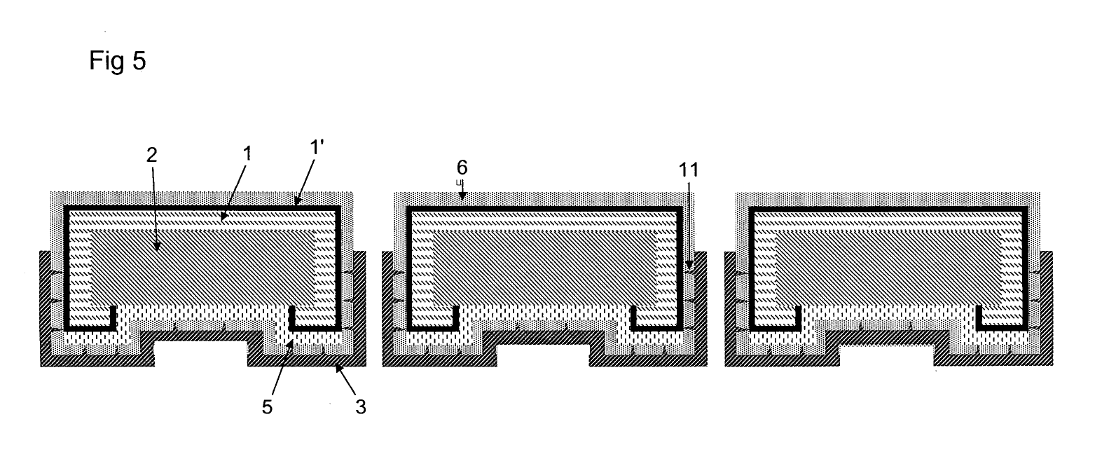

FIG. 5 shows a cross-section of an inventive solar cell having a passivated front surface. Passivation of the front surface of the solar cell can be achieved by depositing a dielectric film, e.g. silicon nitride as shown in FIG. 3. This film can either be deposited directly after the solar cell deposition process or after the rear metallization. The order of the steps constitutes a trade-off between passivation quality and contact resistance. Alternatively, passivation can be achieved with the growth of a dielectric layer 6, e.g. thermal oxide. The dielectric layer 6 is grown after the insulator deposition and solar cell deposition steps, regardless of their order (insulator first is depicted here). A metal layer 3 is formed over the rear surface and partially through the holes. This metal makes contact to the emitter at points where it spikes through the dielectric layer 11.

After passivation is achieved and the emitter contact is made, the next step is to create the base contact. The shape of the rear contact pattern depends on the conductivity of the substrate. If a non-conductive substrate is used, then a fully interdigitated pattern with evenly spaced (approximately 1 mm pitch) base and emitter contact fingers will be necessary. If the substrate is conductive, then it is possible to have less base contact fingers. In this case, the via hole spacing can be optimized within the wide (up to a few centimeters) emitter contact fingers. The few base contact fingers must be thickened, e.g. with electro-plating, to enable conduction of the relatively high currents. All diagrams here show contact structures for conductive substrates.

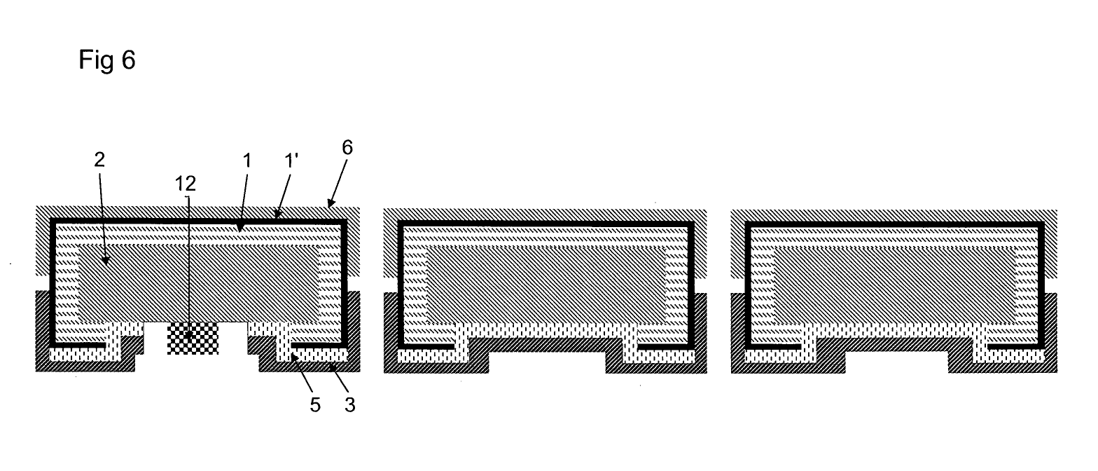

To get access to the base, areas of the emitter contact need to be removed, by masked etching for example (FIG. 6). Then the base contact metal 12 must be formed by an aligned process, e.g. screen printing or masked evaporation.

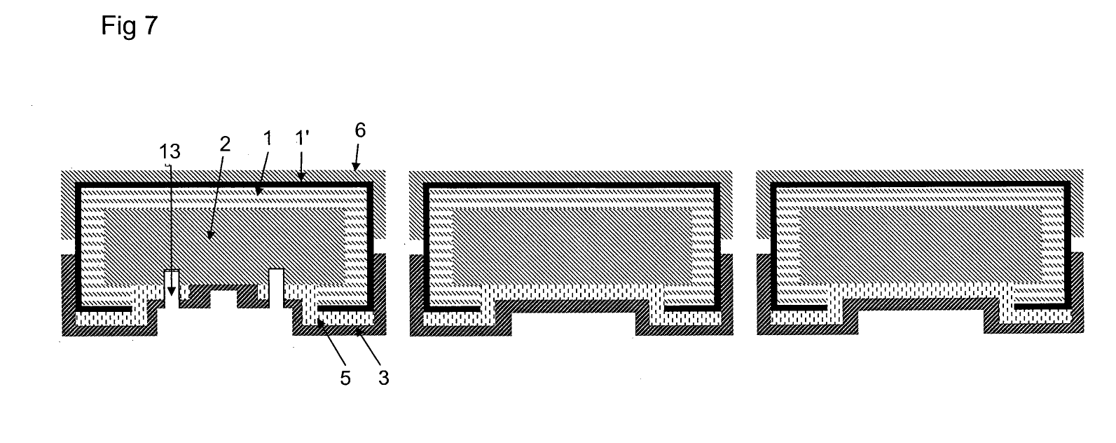

Alternatively, if the insulating layer had been partially removed, e.g. by laser ablation, in the base contact regions prior to the formation of the emitter metal contact (FIG. 7), then the base contact region could subsequently be isolated with trenches, e.g. laser scribes 13.

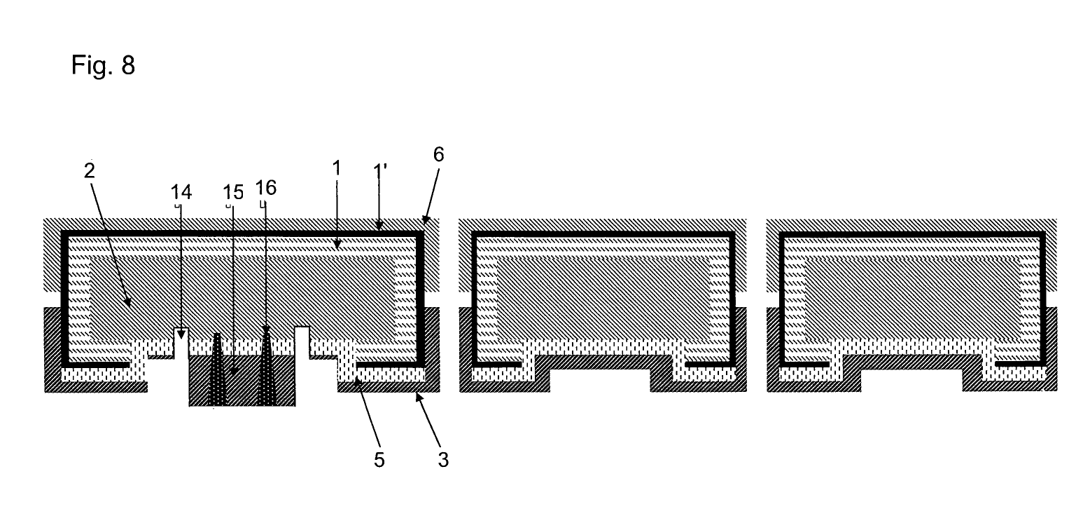

The rear contact pattern can also be defined using a self-aligned process, which is a significant simplification (FIG. 8). Laser trenches are scribed to isolate the base contact region from the emitter contact 14. If the base contact fingers are widely spaced then, they must be thickened to reduce series resistance 15. Then, this metal region is connected to the substrate by laser-fired contacts 16 which are points (or lines, or an area) where a laser is used to melt through the insulating layer.

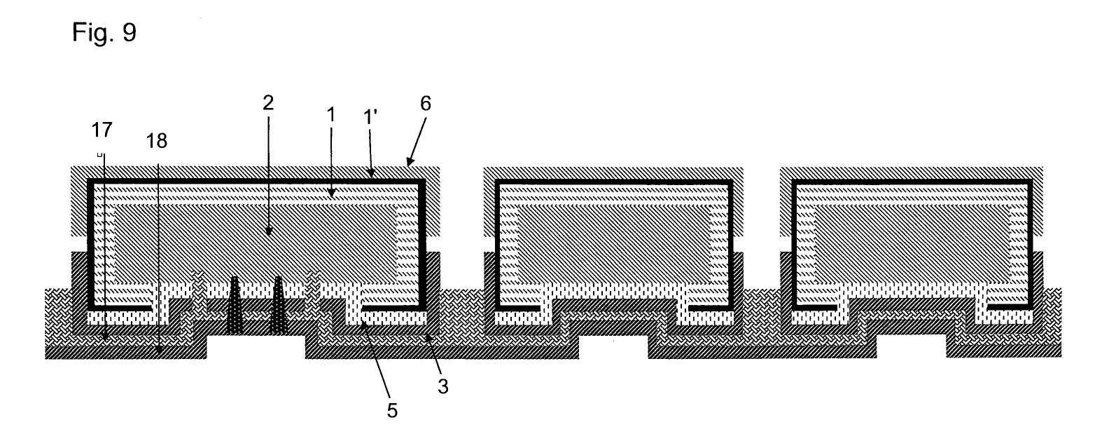

There is a different method which avoids thickening the contact fingers (FIG. 9). After the laser trenches are formed, a resistive layer 17 is deposited followed by another layer of metal 18. Laser-fired contacts connect this second metal layer to the substrate and so it becomes the base contact. There must be a strip at one edge of the solar cell without the resistive layer or the second layer of metal, e.g. formed by masking, to enable access to the emitter contact for cell interconnection purposes.

The further reference signs of FIGS. 4 to 9 correspond to those of FIG. 3.

1. Thin-film solar cell with a front-side where the light enters and a rear-side having
a non-solar grade substrate having at least one via hole connecting the front-side with the rear-side;
at least one photovoltaically active deposited base layer and at least one emitter layer formed at least in regions of the front-side and wrapped through said via hole from the front-side to the rear-side providing an emitter wrap-through (EWT) con-tact; and
at least one emitter contact region and at least one base contact region on the rear-side insulated from each other.

2. The solar cell of claim 1,
wherein the fraction of the rear-side which is covered by the emitter layer is minimised or eliminated.

3. The solar cell of claim 1,
wherein the rear-side is able to be damaged without detriment to the cell performance.

4. The solar cell of claim 1,
wherein the substrate is substantially photovoltaically inactive.

5. The solar cell of claim 1,
wherein at least one isolation layer is deposited between the contact region and the base layer and/or the substrate.

6. The solar cell of claim 1,
wherein the solar cell on the front-side further comprises a passivating layer deposited on the emitter layer.

7. The solar cell of claim 6,
wherein the passivating layer is anti-reflective and consists of a dielectric material.

8. The solar cell of claim 7,
wherein the dielectric material is selected from the group consisting of silicon oxide, silicon carbide, silicon nitride and mixtures thereof.

9. The solar cell of claim 8,
wherein the substrate is an electrically conductive material, preferably a doped silicon.

10. The solar cell of claim 1,
wherein the substrate is an electrically insulating material and at least one electrically conductive layer, which is wrapped around said substrate entirely while the emitter layer is not wrapped around entirely having at least one region which is free of an emitter layer.

11. The solar cell of claim 1,
wherein the at least one emitter contact region and at least one base contact region on the rear-side are formed from one continuous electrically conductive layer which is subsequently structured in said regions.

12. The solar cell of claim 1,
wherein the photovoltaically active material is a semiconductor, in particular a group IV semiconductor, group III/V semiconductor and group II/VI semiconductor, preferably selected from the group consisting of silicon, GaAs and CdTe.

13. A process for the manufacture of a thin-film solar cell comprising:
a) Depositing or growing at least one photovoltaically active base layer and forming at least one emitter layer on a non-solar grade substrate having via holes, wherein the layers are applied on the front-side surface, in the via holes and partially on the rear-side of the substrate;
b) Depositing at least one isolation layer on the entire rear-side of the substrate; and
c) Forming at least one emitter contact region and at least one base contact region on the rear-side insulated from each other.

14. The process of claim 13,
wherein in step c) at least one metal layer is formed on the rear-side and the metal layer is structured into at least one emitter contact region and at least one base contact region insulated from each other.

15. The process of claim 13,
wherein the deposition in step a) is a chemical vapour deposition, a physical vapour deposition, a liquid phase epitaxy and/or an evaporation.

16. The process of claim 13,
wherein the growing is an epitaxial layer growth.

17. The process of claim 13,
wherein a passivation layer is deposited on the front-side subsequent to step a).

18. The process of claim 13,
wherein a passivation layer is deposited on the front-side subsequent to step c).

19. The process of claim 13,
wherein an electrically conductive substrate is used.

20. The process of claim 13,
wherein a electrically insulating substrate is used.

21. The process of claim 13,
wherein in step a) the at least one base layer is deposited and subsequently the at least one emitter layer is formed by diffusion.

22. The process of claim 13,
wherein in step a) the at least one base layer and the at least one emitter layer are deposited in-situ.
